(19) United States
(12) Patent Application Publication
(10) Pub. No.: US 2026/0337380 A1
(43) Pub. Date: Oct. 29, 2026

(54) PICKERING EMULSION COMPOSITION FOR HEAT DISSIPATION, HEAT DISSIPATION PASTE USING SAME, AND METHOD FOR MANUFACTURING SAME

(71) Applicant: PUSAN NATIONAL UNIVERSITY INDUSTRY-UNIVERSITY COOPERATION FOUNDATION, Busan (KR)

(72) Inventors: Chae Bin KIM, Busan (KR); Seong Bae MIN, Busan (KR); Yong Su JO, Busan (KR)

(73) Assignee: PUSAN NATIONAL UNIVERSITY INDUSTRY-UNIVERSITY COOPERATION FOUNDATION, Busan (KR)

(21) Appl. No.: 19/111,795

(22) PCT Filed: Feb. 20, 2023
(86) PCT No.: PCT/KR2023/002406

§ 371 Date: Mar. 14, 2025

(30) Foreign Application Priority Data
Oct. 21, 2022 (KR) 10-2022-0136296

(51) Int. Cl. C08K 7/18; C08K 5/053; H05K 7/20

(52) U.S. Cl. CPC C08K 7/18; C08K 5/053; H05K 7/20481; C08K 2201/001; C08K 2201/003

(57) ABSTRACT

A Pickering emulsion composition for heat dissipation, includes a silicone oil; an aliphatic alcohol; and a thermally conductive filler. A Pickering emulsion-based thermal paste includes a liquid matrix comprising a silicone oil and an aliphatic alcohol; and a thermally conductive filler dispersed in the matrix. A method for preparing a Pickering emulsion-based thermal paste, includes preparing a liquid matrix by mixing a silicone oil and an aliphatic alcohol; and adding a thermally conductive filler to the prepared liquid matrix.

### CROSS-REFERENCE TO PRIOR APPLICATIONS

This application is a National Stage Patent Application of PCT International Application No. PCT/KR2023/002406 (filed on Feb. 20, 2023), which claims priority Patent Application No. 10-2022-0136296 (filed on Oct. 21, 2022), which are all hereby incorporated by reference in their entirety.

### BACKGROUND

The present invention relates to heat dissipation material technology, and more specifically, to a Pickering emulsion composition for heat dissipation, a thermal paste including the same, and a method for preparing the same.

Recently, as electronic components have become more compact, the heat generated per unit area of the device, i.e., heat density, has increased. If the heat generated during the use of the device is not dissipated within a short period of time, it can cause the device to overheat, shorten the lifespan, reduce the reliability, deteriorate the performance, and even cause the device to explode. To solve this problem, it is important to dissipate unnecessary heat, generated during equipment operation, from the heat source to a heat sink using a thermal interface material (TIM) with high thermal conductivity.

Until now, polymer composites that can exhibit both the advantages of lightweight, moldable polymers and the advantages of metal/ceramic fillers have been widely used as Times. Polymer composites are in a form in which polymer resins are impregnated with metal or ceramic fillers, and are suitable as TIMs because they can exhibit the moldability and flexibility of polymers while exhibiting the thermal conductivity of fillers.

Polymer composites can be divided into metal-based polymer composites and ceramic-based polymer composites depending on the filler used. Metal-based polymer composites contain gold (Au), silver (Ag), copper (Cu) or the like as a metal filler, and thus can exhibit very high thermal conductivity, but they are not suitable for use in electronic devices that require insulation because they exhibit electrical conductivity, and it is difficult to ensure lightness, due to the high density of the metal. Ceramic-based polymer composites contain alumina, boron nitride, silica or the like as a ceramic filler, and thus, unlike metal polymer composites, they can ensure insulation, are stable in the air, and are inexpensive, but they have a relatively low thermal conductivity, and thus have a disadvantage in that a high filler content is required to ensure sufficient thermal conductivity.

In addition, TIM exists in various forms depending on the intended use, and representative forms thereof include paste, phase change material (PCM), adhesive, and pad forms. TIM is applied between a heat source and a heat sink, but since the surfaces of the heat source and the heat sink are actually very rough, it is very important to apply TIM with a minimum gap (air layer) between the two interfaces. This is because the thermal conductivity of the gap (air) is very low, which hinders effective heat transfer. In other words, it is very important to apply a TIM with high thermal conductivity, thereby effectively filling the space between the two rough surfaces, thus maximizing the actual contact area.

A TIM that can satisfy these conditions well is a paste formulation, and generally, this thermal paste is a polymer composite in which ceramic filler is dispersed in a low-molecular-weight/high-molecular-weight silicone matrix. Although the silicone matrix of the silicone thermal paste has good spreadability and excellent heat and weather resistance, but has a disadvantage in that, since it has a very low thermal conductivity of about 0.2 W/m·K, and thus even when it is filled with a high content of filler, it is difficult to secure a thermal conductivity of 1.5 to 2 W/m·K or higher. In addition, the long-term stability thereof under general TIM application conditions such as heat and pressure is poor.

Accordingly, there is a need for technology for preparing a thermal paste having both high thermal conductivity and high stability.

### SUMMARY

An object of the present invention is to provide a Pickering emulsion composition for heat dissipation having both excellent thermal conductivity and stability.

Another object of the present invention is to provide a thermal paste based on the Pickering emulsion composition and a method for preparing the same.

To achieve the above objects, the present invention provides a Pickering emulsion composition for heat dissipation, including: a silicone oil; an aliphatic alcohol; and a thermally conductive filler.

The silicone oil may be selected from the group consisting of dimethyl silicone oil, methyl phenyl silicone oil, methyl hydrogen oil, fluorosilicone oil, amino-modified silicone oil, and epoxy-modified silicone oil.

The aliphatic alcohol may be selected from the group consisting of glycerol, ethylene glycol, propylene glycol, butylene glycol, neopentyl glycol, trimethylolethane, trimethylolpropane, and di(trimethylolethane), di(trimethylolpropane).

The silicone oil and the aliphatic alcohol may be included at a volume ratio of 1:(0.1 to 2).

The thermally conductive filler may be selected from the group consisting of alumina, magnesia, boron nitride, silicon nitride, and silica.

The thermally conductive filler may be a spherical filler having an average diameter of 0.1 to 100 μm.

The thermally conductive filler may be included in an amount of 10 to 60 parts by volume based on 100 parts by volume of the composition.

The present invention provides a Pickering emulsion-based thermal paste including: a liquid matrix including a silicone oil and an aliphatic alcohol; and a thermally conductive filler dispersed in the matrix.

The thermally conductive filler may form a segregated network in the matrix.

The paste may have improved thermal conductivity.

The paste may have improved stability to heat and moisture.

The paste may be recycled or reused.

The present invention also provides a method for preparing a Pickering emulsion-based thermal paste, including: a step of preparing a liquid matrix by mixing a silicone oil and an aliphatic alcohol; and a step of adding a thermally conductive filler to the prepared liquid matrix.

The composition for heat dissipation and thermal paste according to the present invention are prepared by forming a Pickering emulsion by adding an aliphatic alcohol to a suspension-type thermal paste, which was conventionally used in the form of a simple mixture of silicone oil and alumina filler, and may have better thermal conductivity and stability.

As the thermally conductive filler in the Pickering emulsion according to the present invention forms a segregated network structure, the Pickering emulsion may perform heat transfer more effectively, and thus may be used as a heat dissipation material in various fields.

In addition, the method for preparing a thermal paste according to the present invention may prepare a thermal paste, which can exhibit high thermal conductivity, stability, and applicability, in a simple and environmentally friendly manner at low cost without a complicated preparation process for conventional thermal pastes, expensive surfactants, or post-treatment processes, and the filler may be recovered and recycled from the thermal paste using a simple centrifugation method.

In addition, the preparation method may be immediately applied to the industry for efficient preparation and further enables mass production, and thus it may contribute to the production and technological development of thermal interface materials in the future.

### BRIEF DESCRIPTION OF THE DRAWINGS

FIG. 1 shows the results of measuring the thermal conductivity and yield stress of a thermal paste as a function of the filler content according to one experimental example of the present invention. Specifically, (a) shows the thermal conductivities of SA03, GA03, and SG5:5A03 as a function of the filler content, (b) shows the yield stresses of SA03, GA03, and SG5:5A03 as a function of the filler content, (c) shows the thermal conductivities of SA90, GA90, and SG5:5A90 as a function of the filler content, and (d) shows the yield stresses of SA90, GA90, and SG5:5A90 as a function of the filler content, wherein SA03, GA03, SA90, GA90, SG5:5A03, and SG5:5A90 represent silicone oil+3 μm alumina, glycerol+3 μm alumina, silicone oil+90 μm alumina, glycerol+90 μm alumina, a 5:5 (v/v) mixture of silicone oil and glycerol+3 μm alumina, and a 5:5 (v/v) mixture of silicone oil and glycerol+90 μm alumina, respectively. (e) and (f) show the thermal conductivities of thermal pastes, predicted by the Bruggeman model. Specifically, (e) shows predicted values obtained by fixing the thermal conductivity of the matrix to 0.2 W/m·K and changing the thermal conductivity of the filler, and (f) shows predicted values obtained by fixing the thermal conductivity of the filler to 100 W/m·K and changing the thermal conductivity of the matrix.

FIG. 2 shows optical microscope (OM) images of single glycerol matrices (GA03) containing 3 μm alumina filler and having filler contents of 10 vol % (a), 20 vol % (b), 30 vol % (c), 40 vol % (d), and 50 vol % (e), respectively. The scale bar represents 20 μm.

FIG. 3 shows optical microscope (OM) images of silicone oil/glycerol emulsions (SG5:5A03) containing 3 μm alumina filler and having filler contents of 0 vol % (a), 10 vol % (b), 20 vol % (c), 30 vol % (d), 40 vol % (e), and 50 vol % (f), respectively. The scale bar represents 50 μm.

FIG. 4 shows optical microscope (OM) images of silicone oil/glycerol emulsions (SG5:5A90) containing 90 μm alumina filler and having filler contents of 20 vol % (a), 30 vol % (b), 40 vol % (c), and 50 vol % (d), respectively. The scale bar represents 50 μm.

FIG. 5 is a graph showing the changes in thermal conductivities of thermal paste samples as a function of the yield stress according to another experimental example of the present invention.

FIG. 6 schematically shows the heat transfer pathways in different thermal pastes. Specifically, (a) shows a suspension-type thermal paste, and (b) shows a Pickering emulsion-type thermal paste.

FIG. 7 shows changes in complex viscosity, yield stress, and thermal conductivity of thermal paste samples under various temperature conditions according to another experimental example of the present invention. All samples were annealed at 50, 75, and 100 °C for 1 hour before measurement, and then cooled to room temperature, followed by measurement. Specifically, (a) shows the complex viscosity of GA03_30 as a function of the angular frequency, (b) shows the complex viscosity of SG5:5A03_30 as a function of the angular frequency, (c) shows the yield stresses of GA03_30 and SG5:5A03_30, (d) shows percentage changes in the yield stresses shown in (c) with respect to the values measured at 25 °C, (e) shows the thermal conductivities of GA03_30 and SG5:5A03_30, and (f) shows percentage changes in the thermal conductivities shown in (e) with respect to the values measured at 25 °C.

FIG. 8 shows the results of measuring the hygroscopicities of thermal paste samples according to another experimental example of the present invention. Specifically, (a show the hygroscopicities of GA03 and SG5:5A03 with varying contents at room temperature and 95% relative humidity, and (b) shows normalized mass values.

FIG. 9 shows the weight losses of alumina recovered from silicone oil/glycerol emulsions (SG5:5A03) containing 3 μm alumina filler and pure alumina with increasing temperature in a nitrogen atmosphere.

### DETAILED DESCRIPTION

Hereinafter, the present invention will be described in detail.

The present inventors have prepared a Pickering emulsion-type paste by incorporating a thermally conductive filler into a matrix obtained by mixing silicone oil and glycerol, which are immiscible with each other, in order to prepare a thermal paste having both high thermal conductivity and high stability, and have found that the Pickering emulsion-type paste has excellent thermal conductivity and stability, thereby completing the present invention.

The present invention provides a Pickering emulsion composition for heat dissipation, including: a silicone oil; an aliphatic alcohol; and a thermally conductive filler.

In this specification, “Pickering emulsion” means an emulsion containing two insoluble phases stabilized using solid particles, unlike a conventional emulsion containing two immiscible phases thermodynamically stabilized using a surfactant.

The silicone oil is a liquid silicone resin having a relatively low degree of polymerization, and examples thereof include, but are not limited to, dimethyl silicone oil, methyl phenyl silicone oil, methyl hydrogen oil, fluorosilicone oil, amino-modified silicone oil, epoxy-modified silicone oil, and the like.

The aliphatic alcohol may be an aliphatic polyhydric alcohol having relatively low volatility, may be selected from, for example, glycerol, ethylene glycol, propylene glycol, butylene glycol, neopentyl glycol, trimethylolethane, di(trimethylolethane), trimethylolpropane, di(trimethylolpropane), and the like, and is preferably glycerol, without being limited thereto.

The silicone oil and the aliphatic alcohol may be included at a volume ratio of 1:(0.1 to 2), preferably 1:(0.5 to 1.5), without being limited thereto.

The thermally conductive filler is for improving the thermal conductivity of the composition, and may include an inorganic filler such as alumina, magnesia, boron nitride, silicon nitride, or silica. Preferably, it may be selected from spherical fillers having an average diameter of 0.1 to 100 μm, more preferably spherical fillers having an average diameter of 0.1 to 10 μm, such as spherical alumina, spherical magnesia, or spherical silica, without being limited thereto.

The thermally conductive filler may be included in an amount of 10 to 60 parts by volume, preferably 10 to 50 parts by volume, based on 100 parts by volume of the paste composition for heat dissipation, without being limited thereto.

The present invention provides a Pickering emulsion-based thermal paste including: a liquid matrix including a silicone oil and an aliphatic alcohol; and a thermally conductive filler dispersed in the matrix.

The liquid matrix may include a silicone oil and an aliphatic alcohol, and for features corresponding to these components, reference may be made to the above description.

The matrix may contain the silicone oil and the aliphatic alcohol at a volume ratio of 1:(0.1 to 2), preferably 1:(0.5 to 1.5), without being limited thereto.

In general, a silicone-based matrix has good applicability due to its low viscosity and surface energy, but it has low thermal conductivity and low interfacial affinity between the filler and the matrix, and thus phase separation easily occurs in the paste prepared. Accordingly, it is possible to prepare a stable emulsion-type matrix having sufficient viscosity and high thermal conductivity by adding an aliphatic alcohol having higher viscosity and thermal conductivity than the silicone-based matrix. However, since aliphatic polyhydric alcohols such as glycerol have poor long-term stability due to their excellent hygroscopicity, it is desirable to prepare a novel matrix that may be used in the form of a Pickering emulsion by mixing a silicone oil and glycerol at the above-described volume ratio.

For: corresponding to the thermally conductive filler, reference may be made to the above description.

The thermally conductive filler may be included in an amount of 10 to 60 parts by volume, preferably 10 to 50 parts by volume, based on 100 parts by volume of the thermal paste composition, without being limited thereto. As the content of the filler increases, the formation of a heat transfer pathway becomes easier, thereby improving thermal conductivity. However, if the content of the filler excessively increases, the density of the heat dissipation material may increase, making it heavier, and the formulation of the paste may not be maintained, which may lower processability. Therefore, the filler is preferably included in an amount (parts by volume) within the above range.

As described above, a thermal interface material (TIM) is applied between a heat source and a heat sink, and it is very important to apply the TIM with a minimum gap (air layer) between the two interfaces. A paste formulation may satisfy this requirement. The paste formulation has advantages in that it may maintain a short interfacial distance (bond line thickness) even with a small pressure, thereby minimizing thermal resistance occurring at the interface and ensuring high thermal conductivity, does not require a curing process and enables dissipation (damping) by absorbing external stress well.

The thermally conductive filler may be adsorbed along the interface between the insoluble silicone oil and glycerol to form a Pickering emulsion, thereby thermodynamically stabilizing the thermodynamically unstable liquid matrix to form a Pickering emulsion. In addition, the thermally conductive filler may effectively form a filler network in the liquid matrix, and such a filler network structure is called a segregated network. The filler may form a segregated network in a thermodynamically stable Pickering emulsion phase, thereby securing a heat transfer pathway, thus further improving thermal conductivity, and may exhibit a high yield stress and have excellent structural stability and dispersion stability. In addition, this may improve stability to heat and moisture.

Accordingly, the paste is a thermal interface material for ensuring heat dissipation and may be used in various electronic devices.

The paste may be recycled or reused.

According to one experimental example of the present invention, it was confirmed that, when the prepared paste was decomposed and recovered, a high-purity filler without any residual solvent could be recovered and reused.

The present invention also provides a method for preparing a Pickering emulsion-based thermal paste, including: a step of preparing a liquid matrix by mixing a silicone oil and an aliphatic alcohol; and a step of adding a thermally conductive filler to the prepared liquid matrix.

More details will be described in examples below.

Hereinafter, the present invention will be described in detail by way of examples to help understand the present invention. However, the following examples are only intended to illustrate the content of the present invention, and the scope of the present invention is not limited to the following examples. The examples of the present invention are provided to more completely explain the present invention to a person of ordinary skill in the art.

### <Example 1> Preparation of Pickering Emulsion-Type Composite (Thermal Paste)

### 1-1. Experimental Materials

Silicone oil (KF-96, 350 cs) was purchased from Shinetsu Chemical (Japan). Glycerol (≥99.0%) was purchased from Sigma-Aldrich (Republic of Korea). Spherical alumina powders with different sizes (3 μm, 20 μm, and 90 μm) were purchased from Denka (Japan). These chemicals were used as received.

### 1-2. Preparation of Thermal Pastes

To prepare suspension-type thermal pastes as controls, silicone oil or glycerol and alumina of various sizes were weighed. The volume contents of alumina with respect to the total thermal paste volume were 10, 20, 30, 40, and 50 vol %, respectively. Thereafter, the weighed suspension was evenly mixed at 2,000 rpm for 1 minute in a Thinky mixer AR-100 (Thinky, Japan). In order to prevent the formation of bubbles in the paste, defoaming was additionally performed at 2,200 rpm for 1 minute, and mixing was performed at 2,000 rpm for 1 minute. The resulting pastes had flowability despite being incorporated with 50 vol % alumina.

To prepare Pickering emulsion-type thermal pastes, silicone oil and glycerol were first weighed at a volume ratio of 1:1 and then mixed for 1 minute at 2,000 rpm using a Thinky mixer. Thereafter, to stabilize the two unstable liquid matrices, alumina was incorporated in amounts of 10, 20, 30, 40, and 50 vol % based on the total paste volume, and the same defoaming and mixing processes as described above for preparing the suspension-type thermal pastes were performed. The prepared pastes had stable formulations at all the filler contents.

### 1-3. Analysis of Physical Properties

The thermal conductivities of the pastes were measured using a transient plain source method thermal analyzer TPS-2500S (Hot-disk AB, Sweden) in isotropic mode at room temperature. Since the pastes had flowability, the pastes were wrapped in vinyl and then placed in vial caps, each having a depth and diameter of 10 mm and 20 mm, respectively, in order to maintain the formulations. A sensor was then placed between the two identical vial caps containing the paste, and the thermal conductivity was measured by measuring a change in contact resistance and temperature. Rheological properties such as complex viscosity and yield stress were measured in small-amplitude oscillatory shear (SAOS) mode using a rotational rheometer (HR-20, TA Instrument, USA) equipped with 40-mm-diameter parallel plates. The filler structures of the thermal pastes were observed through an optical microscope Eclipse LV100ND (Nikon, Japan). Each sample was spread thinly on a glass slide, stabilized at room temperature for 5 minutes, and then observed from above. To observe the temperature stability of the pastes, the pastes were placed on a heating plate and then heated at 50, 75, and 100 °C for 1 hour each, and then cooled to room temperature. Then, the rheological properties and thermal conductivity of the cooled samples were measured in the same manner as mentioned above. To observe the moisture stability of the thermal pastes, the changes in weight of the pastes at room temperature were measured using an analytical balance AUW220D (Shimadzu, Japan). Each of four vials filled with water was placed in the analytical balance, and when the relative humidity reached 95%, the change in weight of the pastes was recorded at 10-minute intervals. In addition, to compare pure alumina and the alumina recovered from the thermal paste including 3 μm alumina, the weight change rate with increasing temperature was measured by thermogravimetric analysis (TGA) in a nitrogen atmosphere.

### <Experimental Example 1> Measurement of Yield Stress and Thermal Conductivity of Thermal Pastes

Yield stress and thermal conductivity are the most important characteristics that a thermal paste must have. Thermal conductivity is a measure of an object's ability to transfer heat, and yield stress refers to the minimum stress required to deform or flow the structure formed by the particles. The yield stress of the paste owes to the non-covalent interactions between the fillers dispersed in the matrix or to the structure formed by the fillers. Generally, the higher the viscosity of the composite, the higher the yield stress, and the higher the yield stress, the better the structural stability. In other words, a thermal paste having both high thermal conductivity and high yield stress may be considered as the best type of thermal paste.

The present inventors measured the thermal conductivity and yield stress of thermal paste composites obtained by dispersing alumina powders with different sizes and contents in silicone oil, glycerol, and an emulsion consisting of a 5:5 (v/v) mixture of silicone oil and glycerol. The alumina used as filler had a diameter of 3 μm or 90 μm. SA and GA represent suspension-type pastes composed of silicone oil and alumina, and glycerol and alumina, respectively, and SG5:5A represents an emulsion-type paste obtained by incorporating alumina into a liquid matrix composed of a 5:5 (v/v) mixture of silicone oil and glycerol. The number following the sample name represents the diameter of the spherical alumina used.

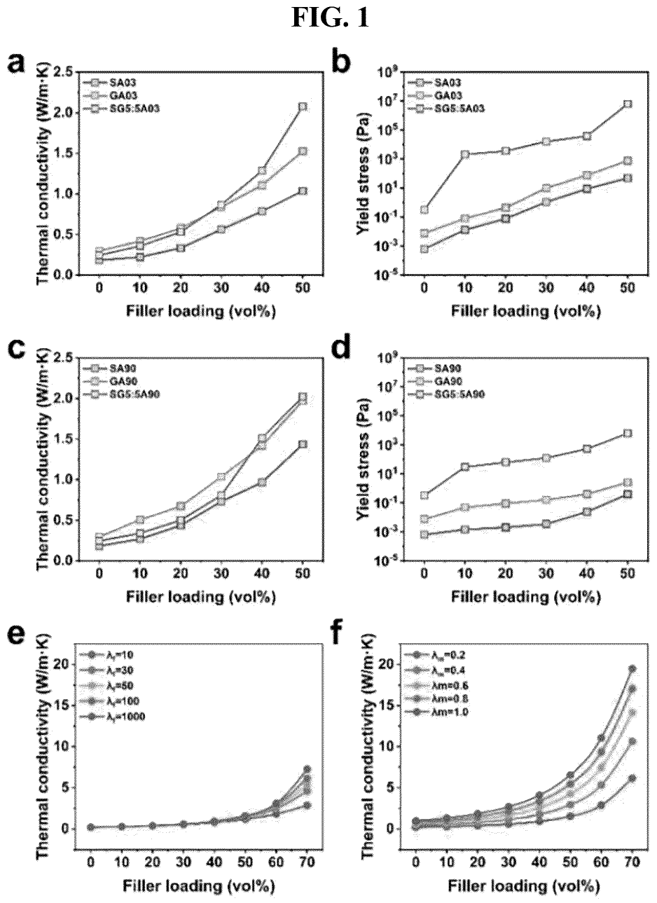

As a result of measuring the thermal conductivities and yield stresses of thermal pastes prepared using silicone oil, glycerol, and glycerol/silicone oil as matrices, as shown in FIGS. 1a to 1d, it was shown that, as the filler content increased, both the thermal conductivity and the yield stress increased regardless of the types of matrix and filler.

First, referring to FIGS. 1b and 1d, the emulsion-type thermal pastes containing silicone oil and glycerol at a ratio of 5:5 always exhibited a higher yield stress than the suspension-type thermal pastes containing silicone oil or glycerol (SA or GA), at all filler contents. This means that the emulsion-type thermal pastes are always more stable than the suspension-type thermal pastes based on a single matrix. In addition, the yield stress increased rapidly when the filler was incorporated at 10 vol % regardless of the size of the incorporated alumina, and the emulsion-type pastes showed a higher yield stress than the suspension-type thermal pastes. This is believed to be because, unlike the suspension-type thermal pastes in which alumina is randomly dispersed, when the liquid resin containing silicone oil and glycerol was used, the unstable interface between silicone oil and glycerol was stabilized by alumina, and the alumina-alumina interaction became stronger, forming a relatively strong structure. In addition, this strongly demonstrates that a Pickering emulsion was formed.

After that, the yield stress also steadily increased as the filler content increased up to 40 vol %. This is believed to be because alumina was continuously located d at the silicone oil/glycerol interface, forming a stronger segregated network structure.

At filler contents higher than 40 vol %, both the yield stress and thermal conductivity increased rapidly (FIGS. 1a and 1c). This is believed to be because alumina filled the space between silicone oil droplets dispersed in the continuous phase (glycerol), thereby forming a segregated network filler structure, thus securing a heat transfer pathway.

As a result, SG5:5A03 [a 5:5 (v/v) mixture of silicone oil and glycerol+3 μm alumina] and SG5:5A90 [a 5:5 (v/v) mixture of silicone oil and glycerol+90 μm aluminal can be expected to be Pickering emulsions in which the interface between two insoluble liquids is stabilized by solid particles.

Referring to FIG. 1a, SG5:5A03 showed higher thermal [silicone oil+3 μm alumina] and GA03 conductivity than SA03 [glycerol+3 μm alumina], and particularly, showed significantly higher thermal conductivity at high filler contents.

The thermal conductivity of the thermal paste is determined by the filler, assuming that the matrix is insulating, and in particular, the thermal conductivity of the thermal paste follows the Bruggeman model of Equation 1 below in the general case where the spherical filler is randomly dispersed in the matrix:

1−V={(λₚ−λc)/(λₚ−λₘ)}*{(λₘ/λ_{c})\hat{ }(1/3)} <Equation 1>

In the above Equation, V represents the volume fraction of the filler, and λₚ, λₘ, and λ_{c} represent the thermal conductivities of the filler, the matrix, and the composite (thermal paste), respectively.

Referring to FIGS. 1e and 1f, it can be seen that, when the thermal conductivity of the filler in the matrix having the same thermal conductivity increased, the increase in the thermal conductivity of the entire composite was relatively small, whereas when the thermal conductivity of the filler in the composite did not change and only the thermal conductivity of the matrix increased, the increase in the thermal conductivity of the entire composite was very large. In other words, the higher thermal conductivity of the matrix is more advantageous for improving the thermal conductivity of the composite.

From this perspective, referring to FIGS. 1a and 1b, in the case of the thermal pastes based on a single matrix, glycerol (0.299 W/m·K) had higher thermal conductivity than silicone oil (0.183 W/m·K), showing higher thermal conductivity in the composite as well. On the other hand, the thermal conductivity of the mixture of silicone oil and glycerol (SG5:5A03) was 0.245 W/m·K, which is an intermediate value between the thermal conductivities of glycerol and silicone oil. However, when 20 vol % or more of alumina was added, the mixture showed higher thermal conductivity than GA03, showing results that did not match the Bruggeman model. This suggests that there is some other influence that overcomes the effect of the matrix on improving thermal conductivity. Taking these results together with the yield stress results, it can be expected that alumina is located at the interface between silicone oil and glycerol to form a segregated network structure between fillers, thereby increasing the yield stress, and thus a more effective heat transfer pathway is formed, resulting in a significant improvement in the thermal conductivity. In addition, it can be determined that SG5:5A03 is of a Pickering emulsion type.

On the other hand, referring to FIG. 1c, it can be confirmed that the increase in thermal conductivity of SG5:5A90 with the increase in the filler content was not as large as that of SG5:5A03. In the same emulsion system with 3 μm alumina, it can be determined that the thermal conductivity increased rapidly due to the segregated structure (FIG. 1a), but when 90 μm alumina was added, the increase in the thermal conductivity and the increase in the yield stress were also small despite having the same matrix system, which is believed to be because the segregated structure was not formed. That is, the size of the alumina was very larger than the size of the formed droplets, and thus the alumina could not effectively stabilize the interface between the two liquids. Therefore, it can be seen that a normal Pickering emulsion was not formed, but rather that the oil droplets and alumina were randomly dispersed.

In summary, it was shown that the larger the size of the filler used in the suspension-type thermal paste containing only silicone or glycerol, the higher the thermal conductivity of the paste, but in the emulsion-type thermal pastes, the thermal conductivity of the pastes was higher when alumina of a smaller size was used, suggesting that the Pickering emulsion and the segregated network structure were effectively formed when 3 μm alumina was used.

To prove these facts, in Experimental Example 2 below, the morphologies of the fillers in the pastes were analyzed using an optical microscope.

### <Experimental Example 2> Analysis of Morphology of Thermal Pastes

As described above, the structure formed by the filler in the thermal paste composite has a greater influence on the thermal conductivity of the entire composite than the thermal conductivity of the matrix itself, and the yield stress of the composite means the minimum force required to deform the structure formed by the filler in the composite and varies depending on the degree of structure formation.

Therefore, in order to understand the relationship between the yield stress/thermal conductivity and the structure formed by alumina, the structure formed by the filler in each of the suspension-type thermal pastes SA03/90 and GA03/90 and the emulsion-type thermal paste SG5:5A03/90 was observed using an optical microscope (OM).

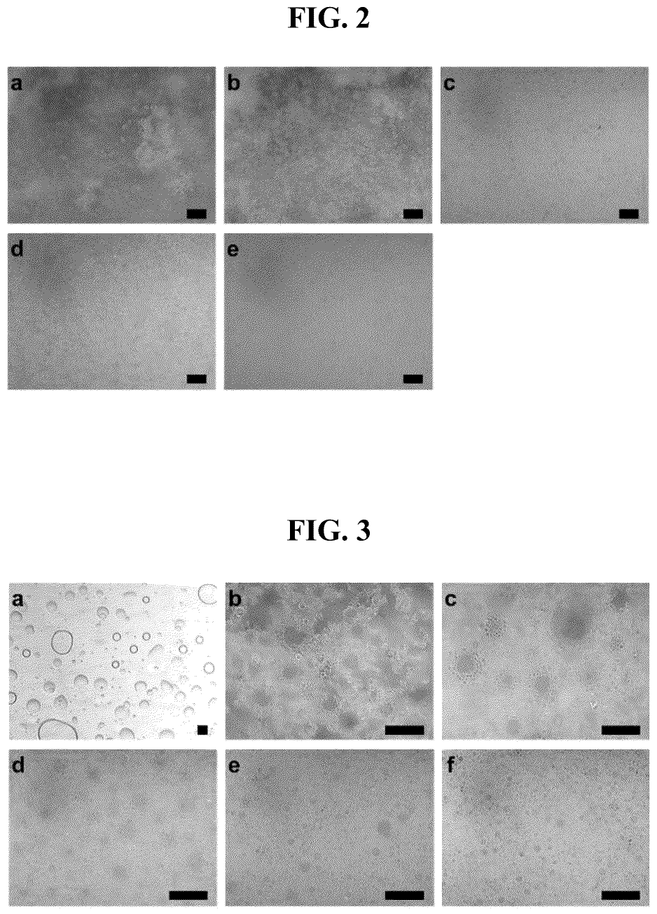

As a result, as shown in FIGS. 2 to 4, the filler dispersed in the single matrix-based suspension containing only silicone oil or glycerol and the filler in the emulsion showed different morphologies.

First, referring to FIG. 2, when the filler was dispersed in the single matrix like GA03, the filler was randomly dispersed, and then, as the filler content increased, the filler tended to be more densely incorporated. For this reason, the thermal conductivity and the yield stress increased rapidly after the percolation threshold (>40 vol %) where the fillers were interconnected (FIGS. 1a to 1d).

On the other hand, the emulsion-type composites (SG5:5A03, and SG5:5A90) containing a mixture of silicone oil and glycerol as from the suspension-type a matrix showed behaviors different complexes containing only silicone or glycerol. Since alumina consists of relatively hydrophilic particles, it shows a behavior of contacting more with glycerol than with silicone oil in the emulsion. In other words, it forms an oil-in-water (O/W) type emulsion in which glycerol is the continuous phase and silicone oil is the dispersed phase.

Therefore, as shown in FIG. 3, the continuous phase represents glycerol and the droplets represent silicone oil. It can be seen that, when silicone oil and glycerol were simply dispersed without alumina, they were in an unstable state in which the droplet size was not constant (FIG. 3a). As 10 vol % of alumina was incorporated, the droplet size becomes relatively constant and the alumina appeared to surround the silicone oil droplets (FIG. 3b). The constant droplet size is because the filler surrounded the droplets to form a stable structure, which can be considered as strong evidence of a Pickering emulsion. Thereafter, as the filler content increased and the matrix ratio decreased, the oil droplet size gradually decreased, and it was observed that adjacent droplets were connected to one another by the filler. Finally, it was observed that the droplets were reduced to a level similar to the alumina size, and that the oil droplets and alumina were densely packed in the glycerol matrix.

Thereby, it can be confirmed that SG5:5A03 formed a stable Pickering emulsion and a segregated network structure by alumina. In addition, it was shown that SG5:5A03 provided a more stable and stronger structure, and the yield stress thereof was higher than those of SA03 and GA03, and that the heat transfer pathway through which heat can pass was continuously formed in SG5:5A03, and the thermal conductivity was also higher than those of SA03 and GA03.

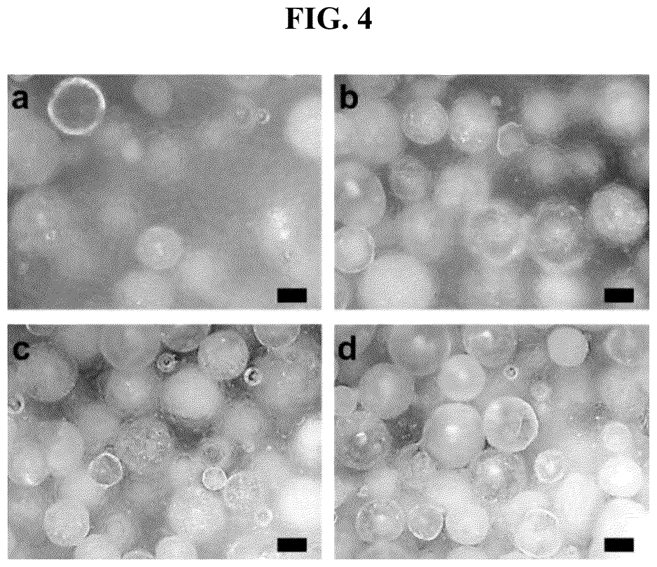

As previously mentioned, it was confirmed that SG5:5A90 had a higher yield stress than SA90 and GA90, like SG5:5A03, and thus had good stability, but the thermal conductivity thereof was not significantly higher than that of GA90. Referring to FIG. 4, this is because the diameter of alumina was larger than that of the silicone oil droplets, and thus the filler did not surround the droplets, but rather the droplets surrounded the filler.

That is, compared to the fillers randomly dispersed in the single matrix, SG5:5A90 behaves like solid particles with the droplets packed between the fillers, which provides good stability (better yield stress than the single matrix-based composite), but does not result in a large improvement in the thermal conductivity because the fillers are not sufficiently connected as in random packing (there is no large improvement in thermal conductivity compared to the single matrix-based composites).

As such, it can be seen that the thermal conductivity and the yield stress are greatly affected by the structure formed by the filler in the composite. Finally, only SG5:5A03 can be considered a Pickering emulsion.

### <Experimental Example 3> Theoretical Analysis of Thermal Pastes

According to the above results, it can be seen that the thermal conductivity is greatly affected by the structure formed by the filler. That is, through the relationship between the yield stress, which represents the measure of the strength of the structure formed by the filler, and the thermal conductivity, it can be seen how effectively the structure formed by the filler improves the thermal conductivity. In addition, the degree to which the formation of the structure by the filler contributes to the thermal conductivity was analyzed using the thermal conductivity prediction model.

Generally, the bulk thermal resistance of a composite used as a TIM is expressed as Equation 2 below:

R_{bulk}=BLT/K_{TIM} <Equation 2>

In the above Equation, R_{bulk} represents the bulk thermal resistance of the TIM, BLT represents the actual contact distance between two solids, and K_{TIM} represents the thermal conductivity of the composite.

In order to interpret BLT, it is important to determine what type of fluid the composite is. Previous studies have shown that the viscosity of a TIM exhibits Herschel-Buckley (H-B) fluid behavior, and BLT depends only on the yield stress of the composite in the equilibrium state. Thus, it has been experimentally reported that the yield stress and thermal conductivity of the TIM have the relationship expressed in Equation 3 below:

K_{TIM}=(1/R_{bulk})C(τ_{y}/P)\hat{ }m <Equation 3>

In the above Equation, C and m are constants, τ_{y} is the yield stress of the composite, K_{TIM} is the thermal conductivity of the composite, and P is the pressure required to bond two solid plates.

Consequently, assuming that R_{bulk} is minimum, that is, close to 0, for all cases and P is constant for all cases, it can be inferred that the thermal conductivity of the composite is proportional to the m power of the yield stress. A high m value indicates a large increase in thermal conductivity relative to the increase in yield stress, and a low m value indicates a small increase in thermal conductivity relative to the increase in yield stress. Therefore, it can be considered that, as the m value increases, the filler forms a structure that improves thermal conductivity more efficiently even when the filler has the same yield stress.

In general, the thermal conductivity and yield stress of the composite have percolation characteristics, and thus the physical properties tend to be maximized when a certain content or more of the filler is incorporated. Referring to FIGS. 1a to 1d, it can be confirmed that the increase slopes of the thermal conductivity and yield stress of all pastes starts to increase at 40 vol %. That is, since the behavior of the zone where percolation occurs and the zone where percolation does not occur differs depending on the content of the filler, it is appropriate that the relationship between the thermal conductivity and the yield stress is examined at less than and more than 40 vol %.

Table 1 below shows the m values calculated according to Equation 3 above for all pastes at less than and more than 40 vol %.

TABLE 1

| Sample | m(<40 vol %) | M(>40 vol %) |
|---|---|---|
| SA03 | 0.18507 | 0.16147 |
| SA20 | 0.31492 | 0.12729 |
| SA90 | 0.31212 | 0.14170 |
| GA03 | 0.13396 | 0.14043 |
| GA20 | 0.29358 | 0.15177 |
| GA90 | 0.47398 | 0.17552 |
| SG5:5A05 | 0.40696 | 0.09433 |
| SG5:5A90 | 0.49102 | 0.11810 |

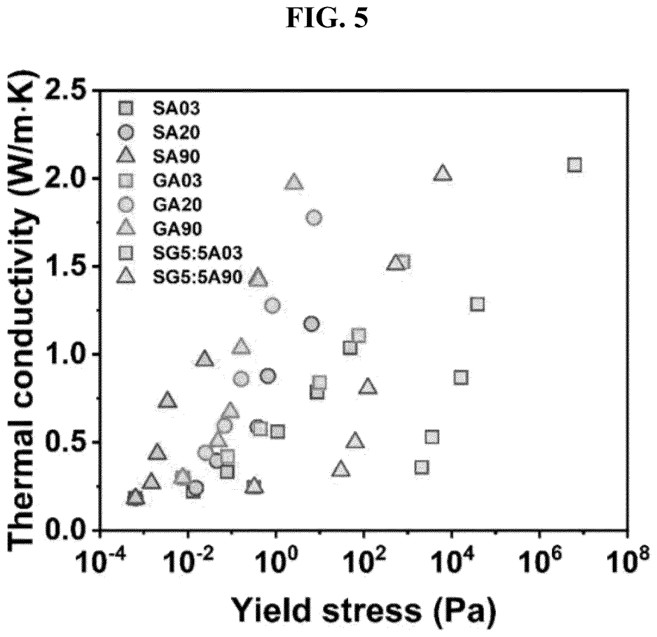

Referring to Table 1 above and FIG. 5 above, all pastes exhibit lower m values at more than 40 vol %. This is because the fillers exhibit percolation behavior in which they are rapidly interconnected at more than 40 vol %, and thus the yield stress increases rapidly compared to the thermal conductivity.

In all pastes, as the size of the incorporated fillers increases, the interfacial thermal resistance that occurs at the interface between the fillers when the fillers contact each other at all contents decreases, thereby increasing the thermal conductivity of the composite. As the filler size increases, the viscosity of the entire composite, i.e., the yield stress, decreases, thereby increasing m.

SG5:5A03 and SG5:5A90 had relatively high m values compared to the suspension-type thermal pastes at <40 vol %, and the m values at >40 vol % decreased rapidly compared to those at <40 vol %. A high m value e means that the increase in thermal conductivity is greater than the increase in yield stress. That is, at less than 40 vol %, unlike single-matrix-based composites, the filler formed a segregated structure so that heat transfer effectively occurred, whereas at more than 40 vol %, the m values decreased rapidly decreased, meaning that the movement of the fillers was greatly restricted by the silicone oil droplets, and the maximum limit at which alumina can be incorporated was reached, so that the yield stress increased significantly compared to the increase in the thermal conductivity.

Taking FIGS. 1 to 5 together, first, as shown in FIGS. 3 and 4, it can be confirmed that SG5:5A03 is in a form in which the filler surrounds the droplets and a segregated structure is formed by the filler, but SG5:5A90 is in a form in which the size of the filler is larger than the size of the droplets, and thus the droplets surround the filler, indicating that only SG5:5A03 is of a Pickering emulsion type.

However, both SG5:5A03 and SG5:5A90 showed large m values compared to the random single matrix-based composites at less than 40 vol % because the fillers had a regular structure due to oil droplets and the increase in thermal conductivity compared to the yield stress was large. However, at more than 40 vol %, both SG5:5A03 and SG5:5A90 showed a large decrease in the m values. That is, at a high content of more than 40 vol %, the increase in yield stress was greater than that in the single matrix composites. This is because oil droplets stabilized to a small size by a large amount of filler in the composite behave like solid particles, significantly restricting the movement of the filler and limiting the volume that can be occupied by the filler, which causes a rapid increase in the yield stress.

As a result, it can be confirmed that both SG5:5A03 and SG5:5A90 containing silicone oil and glycerol as matrices showed better theoretical stability and thermal conductivity than the single matrix-based composites, and among them, SG5:5A03 was of a Pickering emulsion type and had the best stability and thermal conductivity.

Next, it is possible to check how well the internal structure formed by the filler is formed, through the Agari model, which is a model for predicting the thermal conductivity of the composite.

The Agari model is a model proposed to consider the effect of the network formed by the filler at a high content on the thermal conductivity, and may be expressed as Equation 4 below:

log λ_{c}=c_{f}C_{f} log λ_{f}+(1−v_{f})log(Cₚλₚ) <Equation 4>

In the above Equation, λ_{c}, λ_{f}, and λₚ represent the thermal conductivities of the composite, the filler, and the matrix, respectively, and v_{f} represents the volume fraction of the filler

Cₚ is a constant that considers the effect of the secondary structure (crystallinity or crystal size) of the matrix resulting from the incorporation of the filler. That is, it is a measure of whether the filler affects the thermal conductivity of the matrix. A Cₚ of 1 means that the incorporation of the filler does not affect the thermal conductivity of the matrix under ideal conditions. It is known that Cₚ is usually close to 1 in polymer composite materials, and thus, in this experimental example, Cₚ was fixed to 1 (Cₚ=1).

C_{f} is a measure of how efficiently and densely the filler is packed and forms a network. In other words, C_{f} is a measure of the ability to form a heat conduction network. Generally, C_{f} has a value between 0 and 1, and the higher the C_{f}, the denser the network structure of the filler, and thus heat transfer effectively occurs and the thermal conductivity is higher. Consequently, by analyzing the C_{f} value for each case by performing Agari fitting based on the thermal conductivities for the filler volume ratios of all composites, it is possible to find out which composite forms the structure of the filler network that is the most efficient for heat transfer.

Table 2 below shows the results of calculating the C_{f} values of all complex samples after fixing Cₚ to 1.

TABLE 2

| Sample | C_{f} |
|---|---|
| SA03 | 0.536 |
| SA20 | 0.631 |
| SA90 | 0.759 |
| GA03 | 0.616 |
| GA20 | 0.702 |
| GA90 | 0.829 |
| SG5:5A05 | 0.847 |
| SG5:5A90 | 0.829 |

Referring to Table 2 above, SG5:5A03, in which a segregated structure was actually formed by the filler, showed the highest C_{f} value compared to other composites. In other words, it can be confirmed that SG5:5A03 has a strong network structure that is most advantageous for heat transfer.

In addition, SG5:5A90 also showed a relatively high C_{f} value, which is believed to be because the movement of the filler was restricted by the surrounding oil droplets, resulting in a relatively ordered composite compared to the single matrix-based composites.

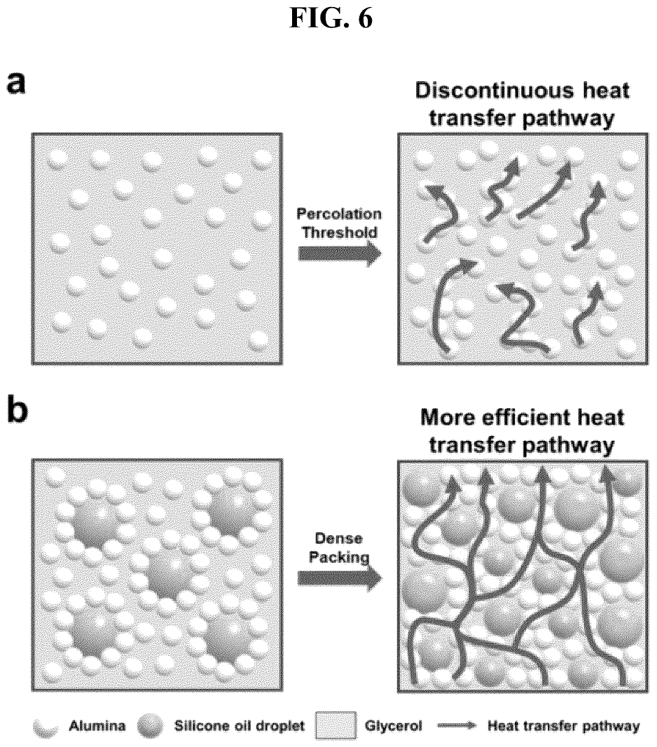

Referring to FIG. 6, it can be confirmed that SG5:5A03, unlike the single matrix-based composites, not only forms an effective heat transfer pathway by forming a segregated structure, but also has high yield stress, i.e., structural stability and dispersion stability. That is, at <40 vol %, a segregated structure is formed, showing a high m value, and at >40 vol %, a dense structure is formed by oil droplets, showing a rapid decrease in the m value and having the highest C_{f} value. As a result, the Pickering emulsion SG5:5A03 has high stability and high thermal conductivity, which is theoretically proven to be due to the segregated structure formed by the filler.

### <Experimental Example 4> Evaluation of Stability of Thermal Pastes

Since thermal pastes are exposed to heat generated from electronic devices for a long time, their long-term stability at high temperatures is important. At high temperatures, a complex fluid-type thermal paste decreases rapidly in its viscosity and begins to flow. If excessive heat is concentrated in this way, the matrix with reduced viscosity flows out of the complex fluid, resulting in a pump-out phenomenon in which stability is reduced, or a dry-out phenomenon in which air fills the area where the matrix disappeared, reducing the heat transfer pathway. In addition, there may be problems of viscosity reduction and filler precipitation, which are the fundamental cause of the disadvantage of thermal paste products whose thermal conductivity gradually decreases with long-term use. In other words, it is important to have stability with little change in viscosity at high temperatures.

In order to observe the temperature-dependent changes in the viscosities of suspension-type and emulsion-type thermal pastes, the temperature-dependent changes in the viscosities of GA03 and SG5:5A03, which have relatively similar thermal conductivities, were observed.

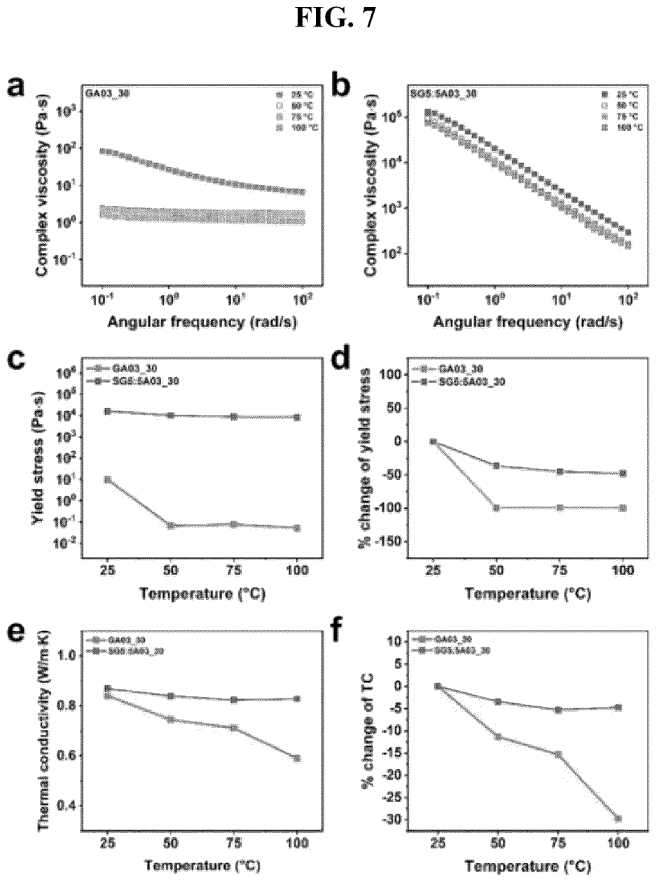

The angular frequency-dependent complex viscosity, temperature-dependent yield stress, and temperature-dependent thermal conductivity of the thermal pastes were examined by sufficiently increasing the temperature from room temperature to 100 °C and then lowering the temperature back to room temperature. As a result, as shown in FIG. 7, it was confirmed that the complex viscosity of GA03 decreased rapidly as the temperature increased, and as the viscosity decreased at high temperatures, the yield stress also decreased rapidly to about 0.5% of that at room temperature. It was shown that the thermal conductivity measured at room temperature after heat treatment at high temperature also decreased by about 30% compared to the thermal conductivity measured without heat treatment. This is because the matrix in the composite rapidly flowed as the temperature increased, causing phase separation with the filler. This result indicates that the thermal stability of GA03 is poor.

On the other hand, it was shown that, in the case of SG5:5A03, the complex viscosity decreased as the temperature increased, but the decrease was very small compared to that of GA03. Also, it can be confirmed that, as the viscosity decreased at high temperatures, the yield stress also decreased to about 50% of that at room temperature, but the decrease was very small compared to that of GA03. It was shown that the thermal conductivity at high temperatures also decreased by about 5% compared to that at room temperature, but the decrease was much smaller than that of GA03. That is, it can be seen that the Pickering emulsion SG5:5A03 is structurally stable because the filler forms a segregated network structure, thereby suppressing phase separation at high temperatures. Thereby, it can be confirmed that SG5:5A03 is very thermally stable.

In addition, thermal paste in electronic devices must maintain a stable formulation even when exposed to extreme environments with high humidity in order to ensure efficient heat dissipation performance.

Glycerol, one of the matrices used in the above Examples, has three —OH functional groups per molecule and thus has hygroscopic properties. Therefore, although GA03 has a thermal conductivity comparable to that of SG5:5A03, which is a Pickering emulsion, it is believed to be unsuitable for use as a thermal paste due to its hygroscopic properties.

To test the hygroscopicities of GA03 and SG5:5A03, the time-dependent weight changes of the thermal pastes with different filler contents were measured under an environment of room temperature and 95% relative humidity, and the results were expressed using Equation 5 below:

Hygroscopicity (%)=[(W1−W0)/W0]×100 <Equation 5>

If each thermal paste has high hygroscopicity, the mass of the thermal paste will increase over time by absorbing water vapor.

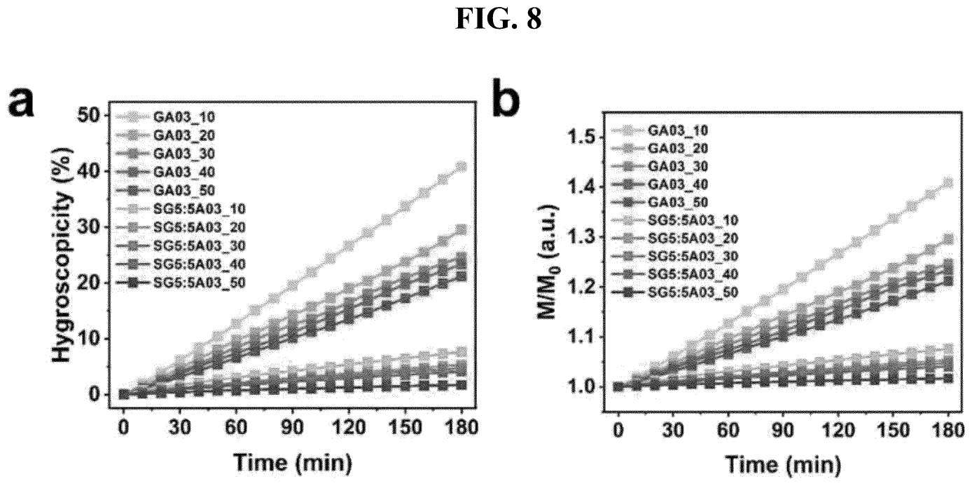

Referring to FIG. 8, all composites showed less weight gain as the filler content increased, due to their improved structural stability and a decrease in the relative amount of the matrix. GA03 showed an increase of approximately 20% compared to its initial weight even at GA03_50 with the highest content, which is due to the high hygroscopicity of glycerol. On the other hand, SG5:5A03 showed only a 7% increase compared to the initial weight even at SG5:5A03_10 (10 vol %) with the lowest filler loading, and SG5:5A03_50 showed only a 1% increase compared to the initial weight, suggesting that it has almost no hygroscopicity. This is due to the segregated structure formed by the filler, although some glycerol is included. As a result, it can be confirmed that SG5:5A03 is a Pickering emulsion and is a thermal paste that is stable even at high temperatures and stable to moisture.

### <Experimental Example 5> Recovery of Thermal Paste Fillers

Recently, the demand for sustainable, eco-friendly, and recyclable materials has increased significantly. In addition, since fillers in polymer composites are usually expensive, the recovery and recycling/reuse of fillers used in composites are of great industrial significance. For this reason, a recovery experiment for recycling the alumina filler from the Pickering emulsion thermal paste prepared in the present invention was conducted.

An experiment was conducted first on the Pickering emulsion thermal paste of SG5:5A03_10 prepared using a low content of the filler. First, centrifugation was performed three times for approximately 10 minutes at room temperature at a rotation speed of 4,000 rpm using a centrifuge (Labogene 1248R). After inducing phase separation between the filler and the matrix by the centrifugation, alumina was recovered. The recovered alumina was washed several times with hexane and distilled water. Hexane was used as a solvent capable of dissolving silicone oil, and distilled water was used as a solvent capable of dissolving glycerol. Thereafter, silicone oil and glycerol were removed from the phase-separated alumina composite using a vacuum filtration device. Additionally, the filtered alumina was dried at 100 °C under vacuum for about 2 days to remove the residual solvent.

In addition, it was checked whether the filler could be recovered from the Pickering emulsion thermal paste of SG5:5A03_50 prepared using a high content of the filler. First, SGA03_50 was diluted with hexane and distilled water, and then the filler was evenly dispersed using a Thinky mixer and a sonicator. Similar to the SGA03_10 thermal paste mentioned above, centrifugation, washing, filtration, and drying were sequentially performed to separate the matrix and filler from each other.

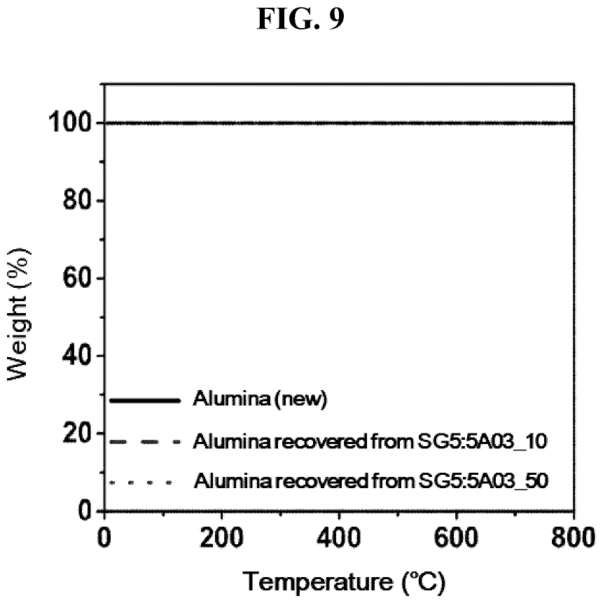

The evaluation of the recovered alumina was performed through thermogravimetric analysis (TGA). Referring to FIG. 9, it can be confirmed that both the alumina recovered from the Pickering emulsion thermal pastes with low and high filler contents showed no weight change caused by the volatilization of distilled water, glycerol, and silicone oil even at high temperatures up to 800 °C, like pure alumina. This means that the recovered alumina can be reused as high-purity alumina without residual solvent in the future.

Since the above-described Pickering emulsion thermal paste has an advantage in that the glycerol/silicone oil matrix and the alumina filler are simply mixed with each other, the filler could be recovered through physical decomposition. This means that the filler separation method may be applied even to the Pickering emulsion heat-radiating paste systems which may be used in various applications. In addition, it is expected that the recovered filler may be recycled for the preparation of new composite materials in the future.

So far, the present invention has been described with reference to the specific embodiments. Those skilled in the art will appreciate that the present invention can be embodied in modified forms without departing from the essential features of the present invention. Therefore, the disclosed embodiments should be considered in descriptive sense only and not for purposes of limitation. The scope of the present invention is defined by the claims rather than the foregoing description, and all differences within the scope equivalent thereto should be construed as being included in the present invention.

1. A Pickering emulsion composition for heat dissipation, comprising: a silicone oil; an aliphatic alcohol; and a thermally conductive filler.

2. The Pickering emulsion composition for heat dissipation according to claim 1, wherein the silicone oil is at least one selected from the group consisting of dimethyl silicone oil, methyl phenyl silicone oil, methyl hydrogen oil, fluorosilicone oil, amino-modified silicone oil, and epoxy-modified silicone oil.

3. The Pickering emulsion composition for heat dissipation according to claim 1, wherein the aliphatic alcohol is at least one aliphatic polyhydric alcohol selected from the group consisting of glycerol, ethylene glycol, propylene glycol, butylene glycol, neopentyl glycol, trimethylolethane, di(trimethylolethane), trimethylolpropane, and di(trimethylolpropane).

4. The Pickering emulsion composition for heat dissipation according to claim 1, wherein the silicone oil and the aliphatic alcohol are comprised at a volume ratio of 1:(0.1 to 2).

5. The Pickering emulsion composition for heat dissipation according to claim 1, wherein the thermally conductive filler is at least one selected from the group consisting of alumina, magnesia, boron nitride, silicon nitride, and silica.

6. The Pickering emulsion composition for heat dissipation according to claim 1, wherein the thermally conductive filler is a spherical filler having an average diameter of 0.1 to 100 μm.

7. The Pickering emulsion composition for heat dissipation according to claim 1, wherein the thermally conductive filler is comprised in an amount of 10 to 60 parts by volume based on 100 parts by volume of the composition.

8. A Pickering emulsion-based thermal paste comprising:
a liquid matrix comprising a silicone oil and an aliphatic alcohol; and
a thermally conductive filler dispersed in the matrix.

9. The Pickering emulsion-based thermal paste according to claim 8, wherein the thermally conductive filler forms a segregated network in the matrix.

10. The Pickering emulsion-based thermal paste according to claim 8, which has improved thermal conductivity.

11. The Pickering emulsion-based thermal paste according to claim 8, which has improved stability to heat and moisture.

12. The Pickering emulsion-based thermal paste according to claim 8, which is recyclable or reusable.

13. A method for preparing a Pickering emulsion-based thermal paste, comprising:
a step of preparing a liquid matrix by mixing a silicone oil and an aliphatic alcohol; and
a step of adding a thermally conductive filler to the prepared liquid matrix.
